(19) United States
(12) Patent Application Publication
(10) Pub. No.: US 2023/0034403 A1
(43) Pub. Date: Feb. 2, 2023

(54) SURFACE EMITTING LASER AND METHOD FOR MANUFACTURING THE SAME

(71) Applicant: Sumitomo Electric Industries, Ltd., Osaka (JP)

(72) Inventor: Hiroyuki HIIRO, Osaka-shi (JP)

(73) Assignee: Sumitomo Electric Industries, Ltd., Osaka (JP)

(21) Appl. No.: 17/858,327

(22) Filed: Jul. 6, 2022

(30) Foreign Application Priority Data
Jul. 20, 2021 (JP) 2021-119803

(51) Int. Cl. H01S 5/183

(52) U.S. Cl. CPC H01S 5/18347; H01S 5/18361; H01S 5/18386

(57) ABSTRACT

A surface emitting laser includes a first reflective layer, an active layer provided on the first reflective layer, and a second reflective layer provided on the active layer. The first reflective layer, the active layer, and the second reflective layer form a mesa, and the mesa has an electrically insulating region and an electrically conductive region. The electrically insulating region is positioned at a center portion of the mesa in a surface direction, and the electrically conductive region includes the first reflective layer, the active layer, and the second reflective layer and is positioned outside the electrically insulating region in such a manner as to surround the electrically insulating region.

### CROSS REFERENCES TO RELATED APPLICATIONS

The present invention contains subject matter related to Japanese Patent Application No. 2021-119803 filed in the Japan Patent Office on Jul. 20, 2021, the entire contents of which are incorporated herein by reference.

### BACKGROUND OF THE INVENTION

### 1. Field of the Invention

The present disclosure relates to a surface emitting laser and a method for manufacturing the surface emitting laser.

### 2. Description of the Related Art

Japanese Unexamined Patent Application Publication No. 2021-009999 discloses a surface-emitting laser diode (surface emitting laser, vertical-cavity surface-emitting laser (VCSEL)). A reflective layer (distributed Bragg reflector (DBR) layer) and an active layer form a mesa. A carrier is injected into the active layer by the passage of electric current through the mesa, so that light is emitted from the mesa to the outside of the surface emitting laser.

### SUMMARY OF THE INVENTION

Heat is generated by the operation of the surface emitting laser, and the temperature of the active layer is increased. As a result of the increase in the temperature of the active layer, a gain is reduced, and it becomes difficult to expand a modulation band to a higher frequency side. Accordingly, it is an object of the present disclosure to provide a surface emitting laser capable of increasing a modulation band of the surface emitting laser and a method for manufacturing the surface emitting laser.

A surface emitting laser according to the present disclosure includes a first reflective layer, an active layer provided on the first reflective layer, and a second reflective layer provided on the active layer. The first reflective layer, the active layer, and the second reflective layer form a mesa. The mesa has an electrically insulating region and an electrically conductive region. The electrically insulating region is positioned at a center portion of the mesa in a surface direction. The electrically conductive region includes the first reflective layer, the active layer, and the second reflective layer and is positioned outside the electrically insulating region in such a manner as to surround the electrically insulating region.

A method for manufacturing a surface emitting laser according to the present disclosure includes stacking a first reflective layer, an active layer, and a second reflective layer on top of one another in this order, forming a mesa out of the first reflective layer, the active layer, and the second reflective layer, and forming an electrically insulating region and an electrically conductive region in the mesa. The electrically insulating region is positioned at a center portion of the mesa in a surface direction. The electrically conductive region includes the first reflective layer, the active layer, and the second reflective layer and is positioned outside the electrically insulating region in such a manner as to surround the electrically insulating region.

### BRIEF DESCRIPTION OF THE DRAWINGS

FIG. 1A is a plan view illustrating, as an example, a surface emitting laser according to a first embodiment.

FIG. 1B is a sectional view taken along line IB-IB of FIG. 1A.

FIG. 2 is a plan view of a mesa.

FIG. 3A is a sectional view illustrating, as an example, a method for manufacturing the surface emitting laser.

FIG. 3B is a sectional view illustrating, as an example, the method for manufacturing the surface emitting laser.

FIG. 3C is a sectional view illustrating, as an example, the method for manufacturing the surface emitting laser.

FIG. 4A is a sectional view illustrating, as an example, the method for manufacturing the surface emitting laser.

FIG. 4B is a sectional view illustrating, as an example, the method for manufacturing the surface emitting laser.

FIG. 5 is a sectional view illustrating, as an example, a surface emitting laser according to a comparative example.

FIG. 6A is a graph illustrating, as an example, results of measurement of thermal resistance.

FIG. 6B is a graph illustrating, as an example, results of measurement of thermal resistance.

FIG. 7A is a diagram illustrating, as an example, an equivalent circuit of the comparative example.

FIG. 7B is a diagram illustrating, as an example, an equivalent circuit of the first embodiment.

FIG. 8 is a graph illustrating, as an example, frequency response characteristics.

FIG. 9A is a sectional view illustrating, as an example, a method for manufacturing a surface emitting laser according to a second embodiment.

FIG. 9B is a sectional view illustrating, as an example, the method for manufacturing the surface emitting laser according to the second embodiment.

FIG. 10A is a sectional view illustrating, as an example, a surface emitting laser according to a third embodiment.

FIG. 10B is an enlarged sectional view of an electrode.

FIG. 10C is a plan view illustrating, as an example, a diffraction grating.

FIG. 11A is a sectional view illustrating, as an example, a surface emitting laser according to a fourth embodiment.

FIG. 11B is an enlarged sectional view of the electrode.

FIG. 12A is a plan view illustrating, as an example, a mesa in a modification.

FIG. 12B is a plan view illustrating, as an example, a mesa in another modification.

### DESCRIPTION OF THE PREFERRED EMBODIMENTS

### Description of Embodiments of Present Disclosure

First, the contents of embodiments of the present disclosure will be listed and described.

(1) A surface emitting laser according to an aspect of the present disclosure includes a first reflective layer, an active layer provided on the first reflective layer, and a second reflective layer provided on the active layer. The first reflective layer, the active layer, and the second reflective layer form a mesa. The mesa has an electrically insulating region and an electrically conductive region. The electrically insulating region is positioned at a center portion of the mesa in a surface direction. The electrically conductive region includes the first reflective layer, the active layer, and the second reflective layer and is positioned outside the electrically insulating region in such a manner as to surround the electrically insulating region. Light that is generated by the active layer resonates between the first reflective layer and the second reflective layer and is emitted from the center portion of the mesa toward the top surface. The electrically insulating region also serves as a heat dissipation path, and thus, heat is less likely to build up inside the electrically conductive region. Heat that is generated in the electrically conductive region is dissipated from the outer peripheral surface and the electrically conductive region. A heat-dissipation performance is improved, so that an increase in the temperature of the active layer in the electrically conductive region is suppressed. A decrease in a gain due to a temperature rise is suppressed, and a modulation band of the surface emitting laser can be increased.

(2) The electrically insulating region may be entirely surrounded by the electrically conductive region. In the electrically conductive region, a width of the active layer in a radial direction can be reduced while the area of the active layer is maintained at a predetermined size. As a result, the heat-dissipation performance is further improved, and an increase in the temperature of the active layer is suppressed. A decrease in the gain due to a temperature rise is suppressed, and thus, the modulation band can be increased.

(3) The electrically insulating region may be an ion-implanted region of the second reflective layer and an ion-implanted region of the active layer. By ion implantation, the electrically insulating region has an electric resistance higher than that of the electrically conductive region. As a result, a current is likely to flow into the electrically conductive region.

(4) The electrically insulating region may be made of an optical material. The electrically insulating region has an electric resistance higher than that of the electrically conductive region. As a result, a current is likely to flow into the electrically conductive region.

(5) The surface emitting laser may further include an electrode disposed on a top surface of the electrically conductive region and electrically connected to the second reflective layer in the electrically conductive region. A surface of the electrode, the surface facing the second reflective layer, may be inclined with respect to a top surface of the second reflective layer. Light propagates through the electrically conductive region, is reflected by the surface of the electrode toward a center portion in a plane of the second reflective layer, and is emitted to the outside of the surface emitting laser from the center portion.

(6) The surface emitting laser may further include a diffraction grating disposed on a top surface of the mesa in such a manner as to be positioned further toward an inner side than the electrode. An inclination angle of the surface of the electrode facing the second reflective layer may be 45 degrees. Light is reflected by the surface of the electrode and diffracted by the diffraction grating, so that the light is emitted to the outside of the surface emitting laser.

(7) An inclination angle of the surface of the electrode facing the second reflective layer may be smaller than 45 degrees. refractive index of the electrically insulating region may be equal to or lower than a refractive index of the electrically conductive region. Light is reflected by the surface of the electrode so as to be incident on the electrically insulating region and reflected by the first reflective layer so as to be emitted to the outside of the surface emitting laser.

(8) A shape of the electrically insulating region in plan view and a shape of the electrically conductive region in plan view may have rotational symmetry with respect to an optical axis. Laser oscillation in a transverse mode that is rotationally symmetric with respect to the optical axis and that has an intensity distribution on the optical axis is obtained.

(9) A method for manufacturing a surface emitting laser includes stacking a first reflective layer, an active layer, and a second reflective layer on top of one another in this order, forming a mesa out of the first reflective layer, the active layer, and the second reflective layer, and forming an electrically insulating region and an electrically conductive region in the mesa. The electrically insulating region is positioned at a center portion of the mesa in a surface direction. The electrically conductive region includes the first reflective layer, the active layer, and the second reflective layer and is located outside the electrically insulating region in such a manner as to surround the electrically insulating region. The electrically insulating region also serves as a heat dissipation path, and thus, heat is less likely to build up inside the electrically conductive region. Heat that is generated in the electrically conductive region is dissipated from the outer peripheral surface and the electrically conductive region. The heat-dissipation performance is improved, so that an increase in the temperature of the active layer in the electrically conductive region is suppressed. As a result, a decrease in the gain of the active layer is suppressed, and a modulation band of the surface emitting laser can be increased.

### Details of Embodiments of Present Disclosure

Specific examples of a surface emitting laser and a method for manufacturing the surface emitting laser according to embodiments of the present disclosure will be described below with reference to the drawings. Note that the present disclosure is not limited to the embodiments, which will be described below as examples, and is to be determined by the claims, and it is intended that meanings equivalent to the scope of the claims and all the modifications within the scope of the claims are included in the scope of the present disclosure.

### First Embodiment

### (Surface Emitting Laser)

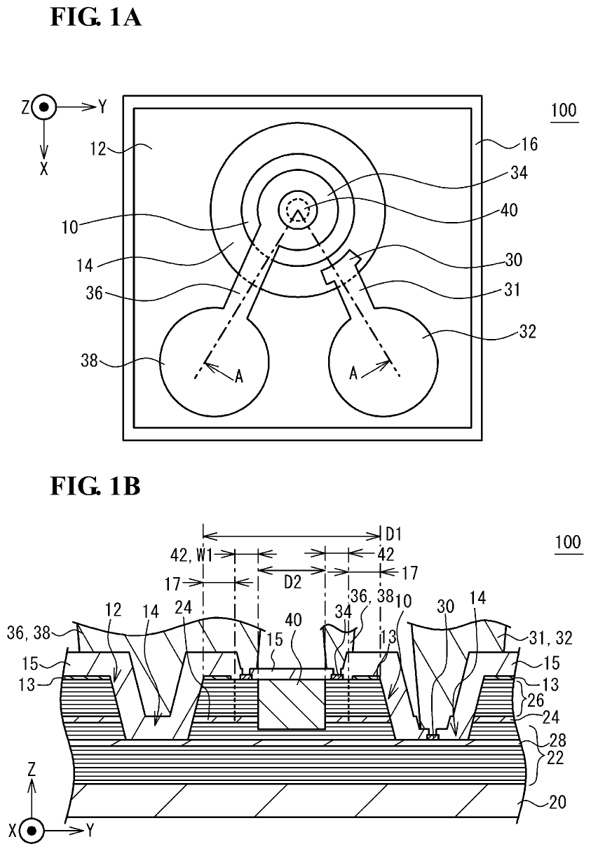

FIG. 1A is a plan view illustrating, as an example, a surface emitting laser 100 according to the first embodiment. FIG. 1B is a sectional view taken along line A-A of FIG. 1A. In the sectional view, the hatching of distributed Bragg reflector (DBR) layers 22 and 26 is omitted.

As illustrated in FIG. 1A, the shape of the surface emitting laser 100 in plan view is a rectangular shape. The two sides of the surface emitting laser 100 extend in the X-axis direction. The other two sides of the surface emitting laser 100 extend in the Y-axis direction. The length of each side is, for example, 240 μm to 250 μm. The Z-axis direction is the same as a stacking direction of a semiconductor layer and the direction of the optical axis of light emitted from the surface emitting laser 100. The X-axis direction, the Y-axis direction, and the Z-axis direction are perpendicular to one another.

The top surface of the surface emitting laser 100 extends parallel to an XY plane. The surface emitting laser 100 includes a mesa 10, a terrace 12, electrodes 30 and 34, and pads 32 and 38 and has recesses 14 and 16. Each of the recesses 14 and 16 is more recessed than the mesa 10 and the terrace 12 in the Z-axis direction. The recess 16 is formed in the outer periphery of the surface emitting laser 100 so as to isolate the surface emitting laser 100 from the other surface emitting lasers 100. In the XY plane, the mesa 10, the pad 32, and the pad 38 each have a circular shape. A diameter D1 of the top surface of the mesa 10 is, for example, 15 μm. The diameter of the pad 32 and the diameter of the pad 38 are each, for example, 70 μm. The recess 14 has an annular shape and surrounds the mesa 10. The terrace 12 is located outside the mesa 10 and the recess 14. The electrode 30 is located in the recess 14. The electrode 34 is located on the mesa 10 and has, for example, a ring-like shape.

As illustrated in FIG. 1B, the surface emitting laser 100 includes a substrate 20, the DBR layer 22 (first reflective layer), an active layer 24, the DBR layer 26 (second reflective layer), and a contact layer 28. The DBR layer 22, the active layer 24, and the DBR layer 26 are stacked in this order on the top surface of the substrate 20. The contact layer 28 is inserted between portions of the DBR layer 22. The DBR layer 22, the active layer 24, and the DBR layer 26 form a laser resonator with a cavity length of λ/2. The wavelength of the light emitted from the surface emitting laser 100 is denoted by λ and is, for example, 800 nm to 950 nm.

The mesa 10 and the terrace 12 are each formed of a portion of the DBR layer 22, the active layer 24, and the DBR layer 26. As will be described later, the mesa 10 includes an electrically insulating region 40 and an electrically conductive region 42. A portion of the DBR layer 22 that is located above the contact layer 28 is included in the mesa 10 or the terrace 12. The recess 14 extends to the top surface of the contact layer 28 in the Z-axis direction. The height of the mesa 10 with respect to the bottom surface of the recess 14 is, for example, 6 μm. The contact layer 28 and a portion of the DBR layer 22 that is located below the contact layer 28 extend below the mesa 10, the terrace 12, and the recess 14. The recess 16 extends to the substrate 20 in the Z-axis direction.

The substrate 20 is, for example, a semiconductor substrate that is made of semi-insulating gallium arsenide (GaAs). The DBR layer 22 is, for example, a semiconductor multilayer film formed by alternately stacking an n-type aluminum gallium arsenide (AlₓGa₁₋ₓAs, 0≤x≤0.3) and an n-type Al_{y}Ga_{1-y}As (0.7≤y≤1) each of which has an optical film thickness λ/4. The wavelength of the light emitted from the surface emitting laser 100 is denoted by λ. The DBR layer 22 is doped with, for example, silicon (Si). The contact layer 28 is made of, for example, an n-type AlGaAs or GaAs.

The active layer 24 includes a plurality of quantum well layers and a plurality of barrier layers alternately stacked together and has a multiple quantum well (MQW) structure. The barrier layers of the active layer 24 are made of, for example, AlGaAs. The quantum well layers of the active layer 24 is made of, for example, indium gallium arsenide (InGaAs). The active layer 24 has an optical gain. A separate confinement heterostructure (SCH) layer (not illustrated) is interposed between the active layer 24 and the DBR layer 22 and between the active layer 24 and the DBR layer 26.

The DBR layer 26 is, for example, a semiconductor multilayer film formed by alternately stacking a p-type AlₓGa₁₋ₓAs (0≤x≤0.3) and a p-type Al_{y}Ga_{1-y}As (0.7≤y≤1) each of which has an optical film thickness λ/4. The uppermost layer of the DBR layer 26 is a p-type GaAs layer that does not contain Al. The DBR layer 26 is doped with, for example, carbon (C). The substrate 20, the DBR layer 22, the contact layer 28, the active layer 24, and the DBR layer 26 may each be made of a compound semiconductor other than those mentioned above.

An insulating film 13 covers the top surface of the mesa 10 and the top surface of the terrace 12. An insulating film 15 covers the top surface of the insulating film 13, the top surface of the mesa 10, a side surface of the mesa 10, the top surface of the terrace 12, a side surface of the terrace 12, the bottom surface of the recess 14, and the bottom surface of the recess 16. The insulating films 13 and 15 are each made of, for example, an insulating material such as silicon oxynitride (SiON), silicon nitride (SiN), or silicon dioxide (SiO₂). The thickness of each of the insulating films 13 and 15 is, for example, 100 μm to 200 μm. A passivation film that covers the insulating films 13 and 15 and the electrodes 30 and 34 may be provided.

The insulating film 15 has an opening located inside the recess 14 and an opening located on the top surface of the mesa 10. The top surface of the contact layer 28 is exposed through the opening located inside the recess 14. The top surface of the DBR layer 26 is exposed through the opening located on the top surface of the mesa 10.

The electrode 30 is an n-type electrode that is disposed inside the recess 14 and is in contact with the top surface of the contact layer 28, which is exposed through the corresponding opening of the insulating film 15. The electrode 30 is made of a metal so as to have, for example, a multilayer structure formed of a gold-germanium alloy (AuGe) and nickel (Ni). The electrode 34 is a p-type electrode that is disposed on the top surface of the electrically conductive region 42 of the mesa 10 and is in contact with the top surface of the DBR layer 26, which is exposed through the corresponding opening of the insulating film 15. The electrode 34 is made of a metal so as to have, for example, a multilayer structure formed of titanium (Ti), platinum (Pt), and Au. The pads 32 and 38 and wiring lines 31 and 36 are each made of a metal such as Au.

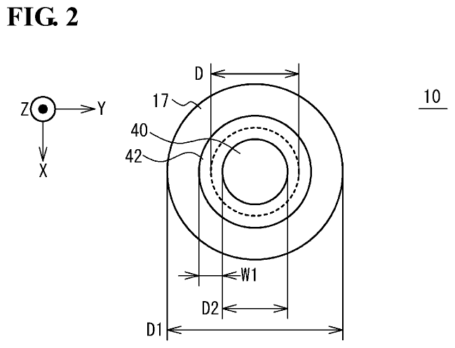

FIG. 2 is a plan view of the mesa 10, and the insulating films, the electrodes, and the pads are not illustrated in FIG. 2. As illustrated in FIG. 1B and FIG. 2, the mesa 10 includes a high resistance region 17, the electrically insulating region 40, and the electrically conductive region 42. In FIG. 1B, the boundary between the high resistance region 17 and the electrically conductive region 42 is indicated by a dotted line. As illustrated in FIG. 2, the high resistance region 17, the electrically insulating region 40, and the electrically conductive region 42 are arranged concentrically with one another in the XY plane. The high resistance region 17 is positioned at the outer peripheral portion of the mesa 10. The electrically insulating region 40 is positioned at a center portion of the mesa 10. The electrically conductive region 42 is positioned between the high resistance region 17 and the electrically insulating region 40 and surrounds the entire outer periphery of the electrically insulating region 40. The shape of the electrically insulating region 40 in plan view is a circular shape. The shape of the electrically conductive region 42 in plan view is an annular shape. In a three-dimensional space, the electrically insulating region 40 has a columnar shape. The electrically conductive region 42 has a tubular shape (a hollow cylindrical shape).

The diameter D1 of the mesa 10 is, for example, 15 μm. A diameter D2 of the electrically insulating region 40 is, for example, 5.25 μm. A width W1 of the electrically conductive region 42 (a width from the electrically insulating region 40 to the high resistance region 17 in a radial direction) is, for example, 1.75 μm.

As illustrated in FIG. 1B, the electrically insulating region 40 extends from the top surface of the DBR layer 26 to a portion of the DBR layer 22 that is between the active layer 24 and the contact layer 28 in the Z-axis direction. In the Z-axis direction, for example, the high resistance region 17 and the electrically insulating region 40 extend from the top surface of the DBR layer 26 and at least reach the bottom surface of the active layer 24. In the Z-axis direction, the electrically conductive region 42 extends from the top surface of the DBR layer 26 to the contact layer 28.

The high resistance region 17 and the electrically insulating region 40 each have an electric resistance higher than that of the electrically conductive region 42. In the high resistance region 17 and the electrically insulating region 40, the DBR layer 26, a portion of the DBR layer 22, and the active layer 24 are mixed-crystallized by ion implantation. In each of the DBR layers 22 and 26, an ion-implanted portion has an electric resistance higher than that of another portion that is not ion-implanted. An ion-implanted portion of the active layer 24 loses its optical activity.

In the electrically conductive region 42, the DBR layers 22 and 26 and the active layer 24 are not ion-implanted and are not mixed-crystallized. In the electrically conductive region 42, the DBR layer 22 has an n-type electrically conductive layer, and the DBR layer 26 has a p-type electrically conductive layer. In the electrically conductive region 42, the active layer 24 has an optical gain. The electrically conductive region 42 has an electrical conductivity higher than that of the high resistance region 17 and that of the electrically insulating region 40 and allows a charge carrier to easily flow therethrough. The electrically conductive region 42 serves as a path of a charge carrier and is a region that oscillates light in the form of a laser beam by its optical gain.

The pads 32 and 38 illustrated in FIG. 1A are each electrically connected to an external device. A charge carrier is injected into the surface emitting laser 100 by applying a voltage to the pads 32 and 38. The high resistance region 17 and the electrically insulating region 40 each have an electric resistance higher than that of the electrically conductive region 42. A charge carrier is less likely to flow into the high resistance region 17 and the electrically insulating region 40 and selectively flows through the electrically conductive region 42 in such a manner as to be injected into the active layer 24. The active layer 24 generates light in response to injection of a charge carrier. The light is oscillated in the form of a laser beam by being reflected by the DBR layers 22 and 26 and is emitted from the top surface of the mesa 10 to the outside of the surface emitting laser 100.

### (Manufacturing Method)

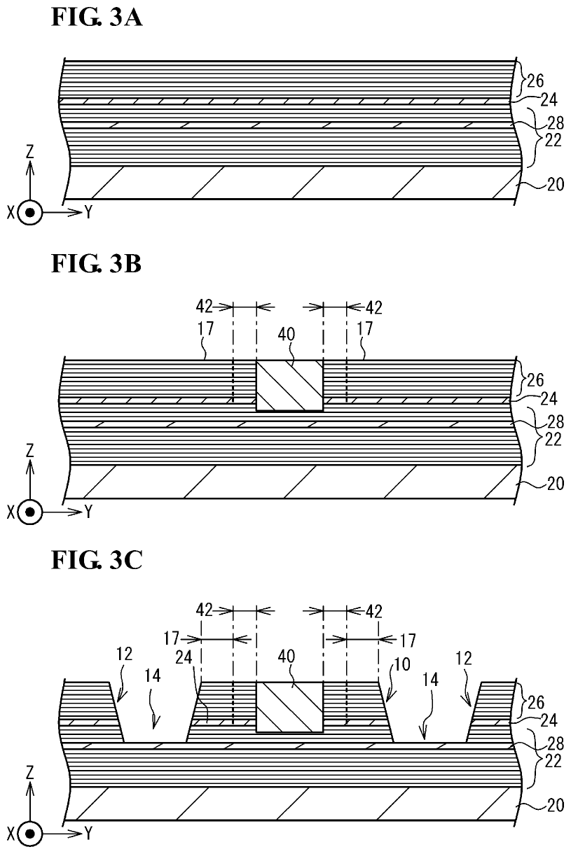

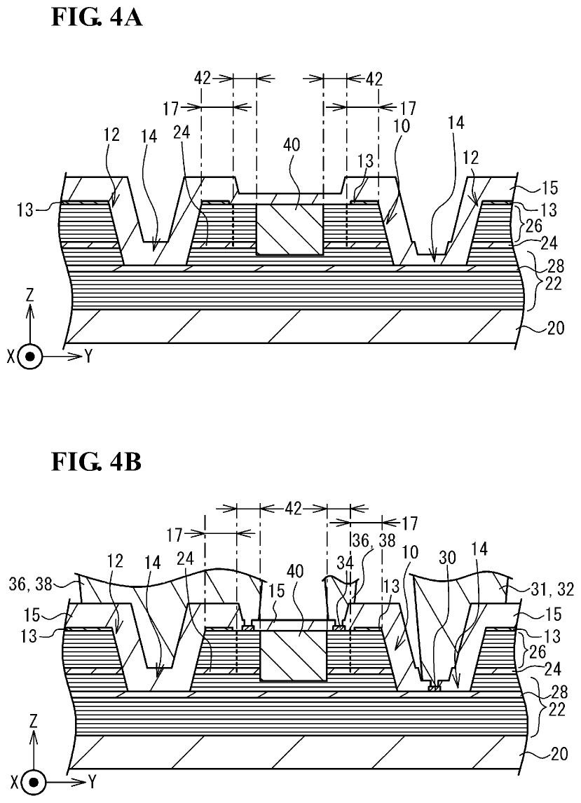

FIG. 3A to FIG. 4B are sectional views illustrating, as an example, a method for manufacturing the surface emitting laser 100. As illustrated in FIG. 3A, the DBR layer 22, the active layer 24, and the DBR layer 26 are epitaxially grown in this order onto the top surface of the substrate 20 by, for example, metal organic chemical vapor deposition (MOCVD) or the like. The contact layer 28 also grows during the growth of the DBR layer 22. After the epitaxial growth, the top surface of the DBR layer 26 is partially covered with a mask (not illustrated).

As illustrated in FIG. 3B, the high resistance region 17 and the electrically insulating region 40 are formed by implanting an ion such as a proton (W). The depth at which an ion is implanted is, for example, larger than the depth from the top surface of the DBR layer 26 to the active layer 24 and does not reach the contact layer 28. A portion into which an ion is not implanted becomes the electrically conductive region 42.

As illustrated in FIG. 3C, the recess 14 is formed. A mask (not illustrated) is formed onto the top surface of the DBR layer 26, and for example, reactive ion etching (RIE) is performed. The DBR layer 26, the active layer 24, and a portion of the DBR layer 22 that is between the active layer 24 and the contact layer 28 are removed such that the recess 14 is formed. The mesa 10 and the terrace 12 are formed at portions covered with the mask. A plurality of mesas 10 and a plurality of terraces 12 are formed onto a wafer (the substrate 20). The mask is removed. In addition, another mask (not illustrated) is formed, and a portion of the DBR layer 22 that is located outside the terrace 12 is removed such that the recess 16, which is illustrated in FIG. 1A, is formed.

As illustrated in FIG. 4A, the insulating films 13 and 15 are formed by, for example, plasma enhanced chemical vapor deposition (PECVD).

As illustrated in FIG. 4B, an opening is formed in a portion of the insulating film 15 that is located in the recess 14. Another opening is formed in a portion of the insulating film 15 that is located above the mesa 10. The electrodes 30 and 34 are formed by vacuum deposition. The wiring lines 31 and 36 and the pads 32 and 38 are formed by sputtering and a plating treatment or the like. A passivation film that covers the insulating films 13 and 15 and the electrodes 30 and 34 may be provided. Portions of the insulating films 13 and 15 that are located in the recess 16 illustrated in FIG. 1A are removed, and the wafer is cut with a dicing machine along the recess 16 such that the surface emitting laser 100 is formed. An array chip in which a plurality of surface emitting lasers 100 are connected to one another may be formed.

### Comparative Example

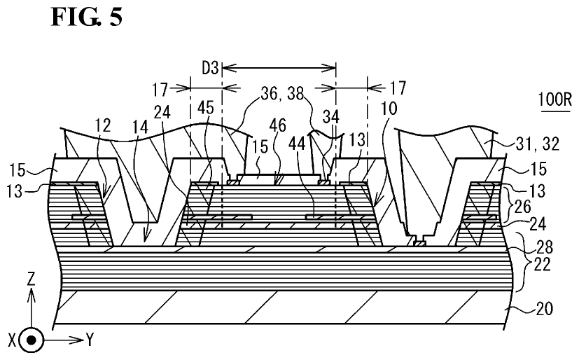

FIG. 5 is a sectional view illustrating, as an example, a surface emitting laser 100R according to a comparative example. The mesa 10 does not have the electrically insulating region 40 and the ring-shaped electrically conductive region 42. The DBR layer 26 includes an oxide confinement layer 44. The DBR layer 26 includes a layer (e.g., an Al_{0.98}Ga_{0.02}As layer) that has an Al composition ratio higher than that of any of the other AlGaAs layers. The oxide confinement layer 44 is formed by oxidizing the Al_{0.98}Ga_{0.02}As layer of the DBR layer 26. The oxide confinement layer 44 extends from an end portion of the mesa 10 toward a center portion of the mesa 10. In the XY plane, the shape of the oxide confinement layer 44 is a ring-like shape. In the step of forming the oxide confinement layer 44, the DBR layers 22 and 26 and a portion of the active layer 24 are oxidized, so that an oxidized region 45 is formed. The oxidized region 45 extends from the side surface of the mesa 10 toward the center of the mesa 10 and is shorter than the oxide confinement layer 44.

The mesa 10 has an unoxidized region 46 formed at a center portion thereof. In the XY plane, the shape of the unoxidized region 46 is a circular shape. The unoxidized region 46 is located on the inner side of the oxide confinement layer 44 and surrounded by the oxide confinement layer 44. The unoxidized region 46 is set to have a diameter D3. The unoxidized region 46 serves as a current path and also serves as an emission region from which light is emitted.

### (Characteristic)

A characteristic of a surface emitting laser will now be described. A frequency response characteristic H of the surface emitting laser may be expressed by the following expression.

$$H ( ω ) ∝ \frac{1}{1 + {( ω / {ω}_{C} )}^{2}} \frac{{ω}_{R}^{4}}{{( {ω}_{R}^{2} - {ω}^{2} )}^{2} + {γ}^{2} {ω}^{2}} \qquad [ Math . 1 ]$$

where: ω stands for frequency, ω_{R} stands for relaxation oscillation frequency, γ stands for attenuation coefficient, and co c stands for cutoff frequency. The cutoff frequency is determined by parasitic capacitance. The factor 1/(1+ω/ω_{C})² on the right side of Math. 1 is a response characteristic of a parasitic capacitance component. As expressed by Math. 1, the frequency response characteristic of the surface emitting laser is affected by the relaxation oscillation frequency and the parasitic capacitance. By increasing the relaxation oscillation frequency and reducing the parasitic capacitance, the frequency response characteristic H can be increased.

The relaxation oscillation frequency ω_{R} may be expressed by the following expression.

$${ω}_{R} = {( \frac{Γ \times Vg}{V \times q} )}^{1 / 2} {\{ a ( T ) ( I - Ith ) \}}^{1 / 2} \qquad [ Math . 2 ]$$

where: Γ stands for an optical confinement factor, V stands for the volume of an effective region of the active layer 24 in which gain is generated, Vg stands for the group velocity of light in a laser resonator, q stands for the amount of carrier charge, I stands for a current input to the surface emitting laser, Ith stands for a threshold current of the surface emitting laser, and a(T) stands for a gain factor. The gain factor depends on a temperature T.

The gain factor a(T) may be expressed by the following expression.

$$a ( T ) = a 0 \frac{A 0 + A 1 \times T + A 2 \times {T}^{2}}{B 0 + B 1 \times T + B 2 \times {T}^{2}} \qquad [ Math . 3 ]$$

where: A0, A1, A2, B0, B1 and B2 are coefficients.

When the temperature T increases, the gain factor a(T) decreases. The relaxation oscillation frequency ω_{R} decreases, and the frequency response characteristic deteriorates. The modulation band is suppressed low. When the temperature T decreases, the gain factor a(T) increases. The relaxation oscillation frequency ω_{R} increases, and the frequency response characteristic improves. In order to increase the modulation band, the heat-dissipation performance of the surface emitting laser may be improved so as to suppress temperature rise.

In the surface emitting laser 100R according to the comparative example, the unoxidized region 46 having a columnar shape serves as a light-emitting region. When the surface emitting laser 100R operates, the unoxidized region 46 generates heat. The high resistance region 17 that is located outside the unoxidized region 46 having a columnar shape serves as a heat path. However, heat builds up on the center side of the unoxidized region 46, and thus, the temperature is likely to increase.

In the surface emitting laser 100 according to the first embodiment, the electrically conductive region 42 having an annular shape serves as a light-emitting region. The high resistance region 17 that is located outside the electrically conductive region 42 having an annular shape and the electrically insulating region 40 that is located inside the electrically conductive region 42 each serve as a heat path, and thus, the heat-dissipation performance is higher than that in the comparative example. Heat is dissipated from the electrically conductive region 42 via the high resistance region 17, the electrically insulating region 40, and the like. Therefore, a temperature rise is suppressed.

More specifically, the temperature T of the surface emitting laser may be approximately calculated by the following expression.

T=T0+(I×V−P0)Zt [Math. 4]

where: T0 stands for the temperature of an environment in which the surface emitting laser is placed, P0 stands for an optical output of the surface emitting laser, Zt stands for the thermal resistance of the surface emitting laser, I stands for current, and V stands for voltage. A portion of the electrical power I×V input to the surface emitting laser is converted into the optical output P0, and another portion of the electrical power I×V is converted into heat. The higher the thermal resistance Zt, the higher the temperature T. The lower the thermal resistance Zt, the lower the temperature T.

The thermal resistance Zt may be approximately expressed by the following expression.

$$ξ \times Z t = \frac{1}{2 \times D 3} \qquad [ Math . 5 ]$$

where: ζ stands for the thermal conductivity of the semiconductor layer and D3 stands for the diameter of the unoxidized region 46. The thermal conductivity of the semiconductor layer is determined by the composition of the DBR layer and the composition of the active layer 24.

The thermal resistance in the first embodiment may be approximately expressed by the following expression.

$$ξ \times Z t = \frac{ln ( 4 h / W 1 )}{{π}^{2} \times D} \qquad [ Math . 6 ]$$

where: h stands for the distance between the substrate 20 serving as a heat sink and the active layer 24, W1 stands for the width of the electrically conductive region 42, and D stands for the diameter of a circle that passes through the center of the electrically conductive region 42 in a width direction. The diameter of the circle is the value obtained by adding the width W1 of the electrically conductive region 42 to the diameter D2 of the electrically insulating region 40 (D=D2+W1, see FIG. 2).

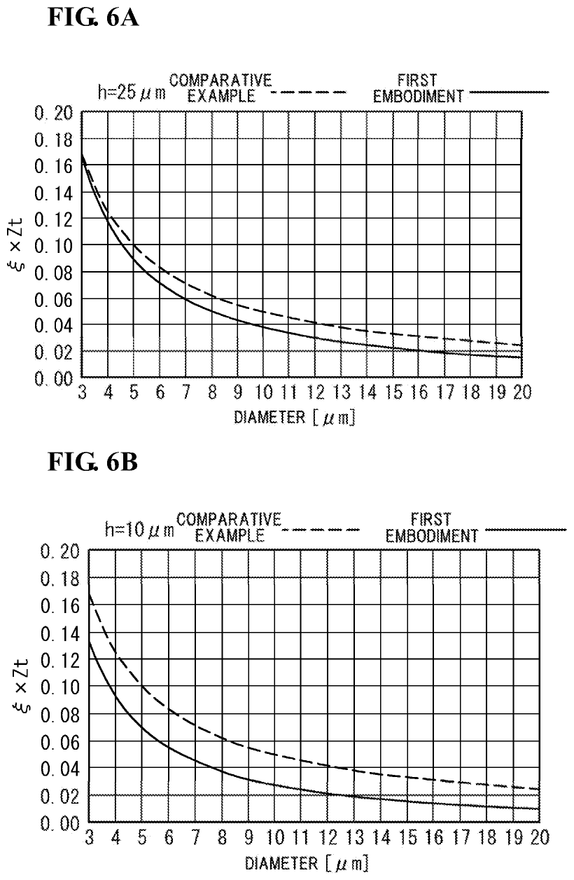

FIG. 6A and FIG. 6B are graphs illustrating, as an example, results of measurement of thermal resistance. The comparative example is indicated by a dashed line. The first embodiment is indicated by a solid line. The horizontal axis denotes the diameter D3 of the unoxidized region 46 or the diameter D. The vertical axis denotes the product of the thermal resistance Zt and the thermal conductivity ζ. The thermal conductivity is common to the comparative example and the first embodiment.

FIG. 6A illustrates the case in which h=25 μm. FIG. 6B illustrates the case in which h=10 μm. In both the case illustrated in FIG. 6A and the case illustrated in FIG. 6B, the thermal resistance in the first embodiment is lower than the thermal resistance in the comparative example. The larger the diameter, the lower the thermal resistance. A temperature rise is suppressed as a result of the thermal resistance decreasing, and the relaxation oscillation frequency ω_{R} increases. The modulation band can be a higher frequency.

Next, parasitic capacitance will be described. As illustrated in FIG. 5, the surface emitting laser 100R according to the comparative example has the oxide confinement layer 44. Since the DBR layer 26 is located on the upper side and the lower side of the oxide confinement layer 44, a parasitic capacitance is generated.

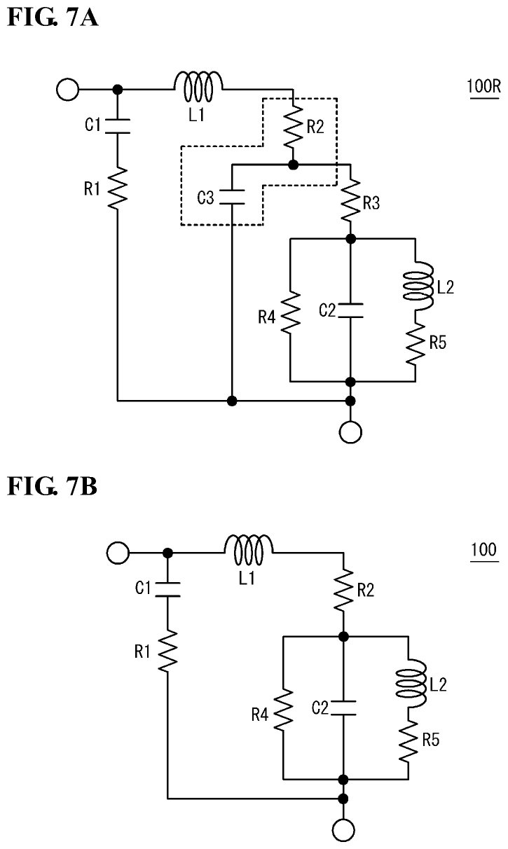

FIG. 7A is a diagram illustrating, as an example, an equivalent circuit of the comparative example. Inductor components of the pad 38 and the wiring line 36 are denoted by L1. A capacitance component of the terrace 12 is denoted by C1. A resistance component of the terrace 12 is denoted by R1. An inductor component of the mesa 10 is denoted by L2. A resistance component of the mesa 10 is denoted by R2, R3, R4, and R5. The resistor R2 corresponds to the resistance of a portion of the DBR layer 26 that is narrowed by being sandwiched by the oxide confinement layer 44. A capacitance component of the mesa 10 is denoted by C2 and C3, and C3 corresponds to the parasitic capacitance that is generated by the oxide confinement layer 44. The equivalent circuit of the active layer 24 is represented by R4, C2, L2, and R5.

As illustrated in FIG. 7A, the capacitor C1 and the resistor R1 are connected in series. The inductor L1 and the resistor R2 are connected in series. A first end portion of the inductor L1 and a first end portion of the capacitor C1 are connected to each other. A first end portion of the resistor R2 is connected to a first end portion of the capacitor C3 and a first end portion of the resistor R3. A second end portion of the resistor R3 is connected to a first end portion of the resistor R4, a first end portion of the capacitorC2, and a first end portion of the inductor L2. A second end portion of the inductor L2 is connected to a first end portion of the resistor R5. An end portion of the resistor R1 is connected to a second end portion of the resistor R4, a second end portion of the capacitor C2, a second end portion of the resistor R5, and a second end portion of the capacitor C3. The resistor R2 and the capacitor C3 form an RC circuit and function as a low-pass filter.

The cutoff frequency ω_{C} in Math. 1 is given by the following expression.

$${ω}_{C} = \frac{1}{Cm \times Rm} \qquad [ Math . 7 ]$$

where: ωₘ stands for a parasitic capacitance component and corresponds to the capacitor C3 in FIG. 7A, and Rm stands for a parasitic resistance component and corresponds to the resistor R2 in FIG. 7A. In the comparative example, a response factor 1/(1+ω/ω_{C})² of a parasitic component increases, and the frequency response characteristic H decreases.

FIG. 7B is a diagram illustrating, as an example, an equivalent circuit of the first embodiment. In the first embodiment, the oxide confinement layer 44 is not formed, and thus, the resistor R3 and the capacitor C3 are not formed as illustrated in FIG. 7B. Since there is no capacitor C3, an RC circuit is not formed. Deterioration of the frequency response characteristic due to a response factor of a parasitic component in Math. 1 is suppressed.

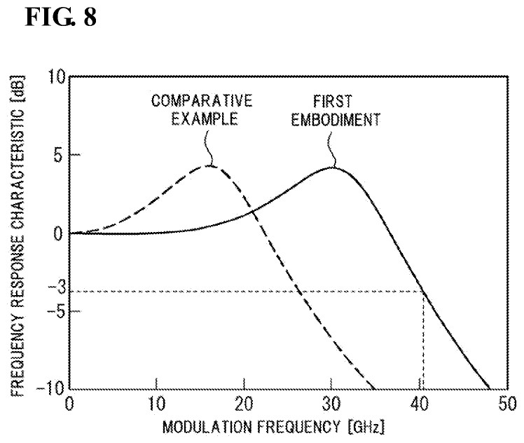

FIG. 8 is a graph illustrating, as an example, frequency response characteristic and results of calculations using the expressions of Math. 1 to Math. 7. A distance h to the heat sink (substrate 20) is set to 10 μm, and a diameter is set to 7 μm. The horizontal axis denotes frequency. The vertical axis denotes frequency response characteristics. The comparative example is indicated by a dashed line. The first embodiment is indicated by a solid line. In the first embodiment, the frequency response characteristic is improved compared with the comparative example. A frequency response characteristic of −3 dB is obtained at 40 GHz.

According to the first embodiment, the mesa 10 has the electrically insulating region 40 and the electrically conductive region 42. As illustrated in FIG. 1B and FIG. 2, the electrically insulating region 40 is positioned at a center portion of the mesa 10. The electrically conductive region 42 is positioned outside the electrically insulating region 40 in such a manner as to surround the electrically insulating region 40. A charge carrier flows through the electrically conductive region 42 and injected into the active layer 24. Light generated by the active layer 24 propagates through the electrically conductive region 42 and is emitted to the outside of the surface emitting laser 100. Since the electrically conductive region 42 has a ring-like shape, heat that is generated in the electrically conductive region 42 is less likely to build up in the electrically conductive region 42 and is dissipated from the outer peripheral surface and the inner peripheral surface of the electrically conductive region 42. The electrically insulating region 40 serves as a heat dissipation path. The heat-dissipation performance is improved, so that a temperature rise is suppressed. The relaxation oscillation frequency becomes higher by suppressing a temperature rise, and thus, the frequency response characteristic is improved. As a result, the modulation band of the surface emitting laser 100 can be increased.

As illustrated in FIG. 2, the electrically conductive region 42 completely surrounds the electrically insulating region 40 in the XY plane. Heat is dissipated from the inner peripheral surface of the electrically conductive region 42 via the electrically insulating region 40. The heat-dissipation performance is improved, so that a temperature rise is suppressed. The modulation band can be increased.

The electrically insulating region 40 includes ion-implanted portions of the DBR layer 26 and the active layer 24. By ion implantation, the DBR layer 26 can be insulated, and the optical activity of the active layer 24 can be lost. The electrically insulating region 40 has an electric resistance higher than that of the electrically conductive region 42. As illustrated in FIG. 3B, the electrically insulating region 40 can be formed together with the high resistance region 17 by a single ion implantation, and thus, the process is simplified.

The smaller the width W1 of the electrically conductive region 42, the lower the thermal resistance Zt, and a temperature rise can be suppressed. In contrast, when the width W1 becomes smaller, the electrically conductive region 42 into which a carrier is injected becomes smaller, and the light output decreases. For example, the width W1 is set in such a manner that the area of the electrically conductive region 42 in the XY plane is approximately equal to the area of the unoxidized region 46 illustrated in FIG. 5. A light output that is at approximately the same level as that in the comparative example can be obtained.

By suppressing an increase in the temperature of the surface emitting laser 100, the deviation (detuning) between the wavelength at which the optical gain of the active layer 24 reaches its peak and the resonant wavelength is suppressed. A decrease in the gain of the surface emitting laser 100 is suppressed, and a decrease in the modulation band is also suppressed.

In the comparative example, since the oxide confinement layer 44 is formed in the DBR layer 26, distribution of the refractive index of the DBR layer 26 becomes discontinuous. In the first embodiment, the oxide confinement layer 44 is not formed in the DBR layer 26. The refractive index of the DBR layer 26 is periodically distributed along the Z-axis direction. The optical loss is reduced. Since an oxide confinement layer is not formed in the surface emitting laser 100, a change in the volume of the DBR layer due to oxidation is suppressed. Stress is less likely to be generated, and yield is improved.

The ring-shaped active layer 24 in the electrically conductive region 42 serves as a Bragg reflection waveguide that is sandwiched between the DBR layers 26 and 22 from the upper and lower sides. When the cavity length in the Z-axis direction including the active layer 24 is λ/2, there is no eigenmode for propagation in a circumferential direction. Thus, light is oscillated in the form of a laser beam not in the circumferential direction, but in the Z-axis direction. The energy that is injected into the surface emitting laser 100 is not used for laser oscillation in the circumferential direction and is supplied to laser oscillation in the Z-axis direction. Although the electrically insulating region 40 and the electrically conductive region 42 are provided, a decrease in the efficiency is suppressed.

### Second Embodiment

The electrically insulating region 40 in the second embodiment is made of an insulating material. The description of a configuration that is the same as that of the first embodiment will be omitted. A plan view of a surface emitting laser according to the second embodiment is the same as FIG. 1A. A sectional view of the surface emitting laser according to the second embodiment is the same as FIG. 1B. The shape of the electrically insulating region 40 and the shape of the electrically conductive region 42 are the same as those illustrated in FIG. 2.

The electrically insulating region 40 is made of, for example, an optical material such as silicon nitride (Si₃N₄), silicon oxide (SiO₂), silicon oxynitride (SiON), aluminum oxide (Al₂O₃), titanium oxide (TiO₂), optical glass, and an optical resin. The optical material is light transmissive and has an insulating property. The refractive index of the electrically insulating region 40 is lower than the refractive index of the DBR layer 26.

### (Manufacturing Method)

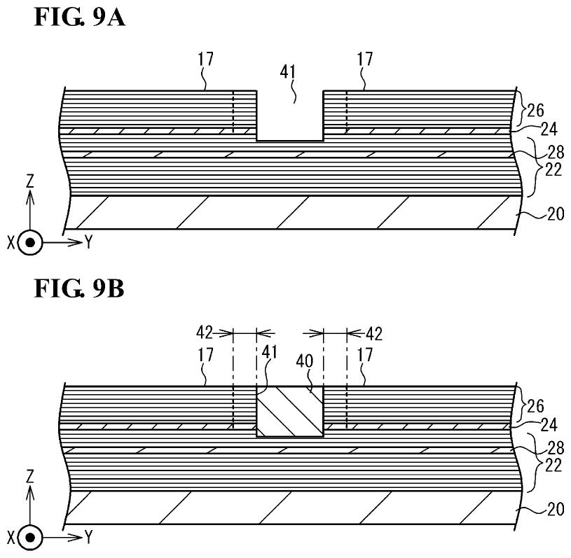

FIG. 9A and FIG. 9B sectional views illustrating, as an example, a method for manufacturing the surface emitting laser according to the second embodiment. After the semiconductor layer has been epitaxially grown as illustrated in FIG. 3A, the DBR layers 22 and 26 and the active layer 24 are partially removed by etching as illustrated in FIG. 9A so as to form a recess 41. As illustrated in FIG. 9B, the electrically insulating region 40 is formed by filling the recess 41 with an insulating material. The subsequent steps are the same as those in the first embodiment.

According to the second embodiment, since the electrically insulating region 40 is made of a light-transmitting and insulating optical material, the electrically insulating region 40 has an electric resistance higher than that of the electrically conductive region 42. A charge carrier can be caused to selectively flow into the electrically conductive region 42. Heat that is generated in the electrically conductive region 42 is dissipated from the outer peripheral surface and the inner peripheral surface of the electrically conductive region 42. The heat-dissipation performance is improved, so that a temperature rise is suppressed. The relaxation oscillation frequency becomes higher, and thus, the frequency response characteristic is improved. As a result, the modulation band can be increased.

In the first embodiment and the second embodiment, the shape of the electrically insulating region 40 in plan view may be a circular shape or may be, for example, an oval shape, a polygonal shape, or the like. The shape of the electrically conductive region 42 in plan view may be an annular shape or may be, for example, an oval annular shape, a polygonal annular shape, or the like. A polygonal annular shape is a ring-like shape having a polygonal inner peripheral surface and a polygonal outer peripheral surface.

### Third Embodiment

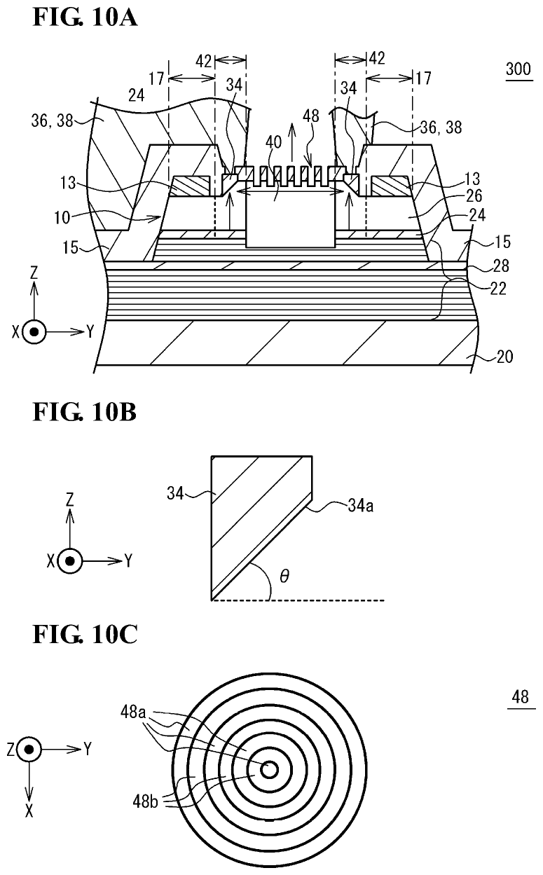

FIG. 10A is a sectional view illustrating, as an example, a surface emitting laser 300 according to the third embodiment. The description of a configuration that is the same as that of the first embodiment or that of the second embodiment will be omitted.

As illustrated in FIG. 10A, the mesa 10 has the electrically insulating region 40 and the electrically conductive region 42. The electrically insulating region 40 may be formed by ion implantation or may be formed by injecting an optical material. As will be described in the fourth embodiment, the refractive index of the electrically insulating region 40 is equal to or lower than the refractive index of the electrically conductive region 42. The mesa 10 includes a diffraction grating 48.

The top surface of the mesa 10 has an inclined surface formed in the electrically conductive region 42. This inclined surface is inclined upward in the Z-axis direction from the outer side of the mesa 10 toward the inner side of the mesa 10. The electrode 34 is disposed on the inclined surface of the electrically conductive region 42.

FIG. 10B is an enlarged sectional view of the electrode 34. As illustrated in FIG. 10A and FIG. 10B, the thickness of the electrode 34 on the outer side of the mesa 10 is large, and the thickness of the electrode 34 on the inner side of the mesa 10 is small. A surface 34a of the electrode 34 faces the electrically conductive region 42 and is inclined with respect to the XY plane. The surface 34a is oriented toward the inside of the mesa 10. An inclination angle θ of the surface 34a illustrated in FIG. 10B is, for example, 45 degrees.

As illustrated in FIG. 10A, the diffraction grating 48 is located on the top surface of the mesa 10 and provided in the electrically insulating region 40. The diffraction grating 48 corresponds to portions of the insulating film 15 and the DBR layer 26 on and in which projections and recesses are periodically formed.

FIG. 10C is a plan view illustrating, as an example, the diffraction grating 48. The diffraction grating 48 has a plurality of projections 48a and a plurality of recesses 48b. The plurality of projections 48a and the plurality of recesses 48b are arranged concentrically with one another. The projections 48a include the insulating film 15 and the DBR layer 26. In the recesses 48b, the insulating film 15 is removed. The recesses 48b include portions of the DBR layer 26 that are more recessed than the projections 48a in the Z-axis direction.

After the mesa 10 has been formed, etching is performed on the mesa 10 so as to form the inclined surface. For example, the diffraction grating 48 is formed by etching the insulating film 15 and the DBR layer 26. The electrode 34 is formed onto the inclined surface of the mesa 10. The surface 34a that is in contact with the mesa 10 becomes an inclined surface.

According to the third embodiment, the heat-dissipation performance is improved, so that a temperature rise is suppressed. The modulation band of the surface emitting laser 300 can be increased. As indicated by arrows in FIG. 10A, light propagates through the electrically conductive region 42 and is reflected by the surface 34a of the electrode 34 so as to propagates in the XY plane. The transverse mode of the light reflected by the surface 34a has an intensity distribution mainly in the electrically insulating region 40. The light is diffracted by the diffraction grating 48 and emitted upward in the Z-axis direction. According to the third embodiment, light can be efficiently extracted to the outside by the surface 34a of the electrode 34 and the diffraction grating 48.

### Fourth Embodiment

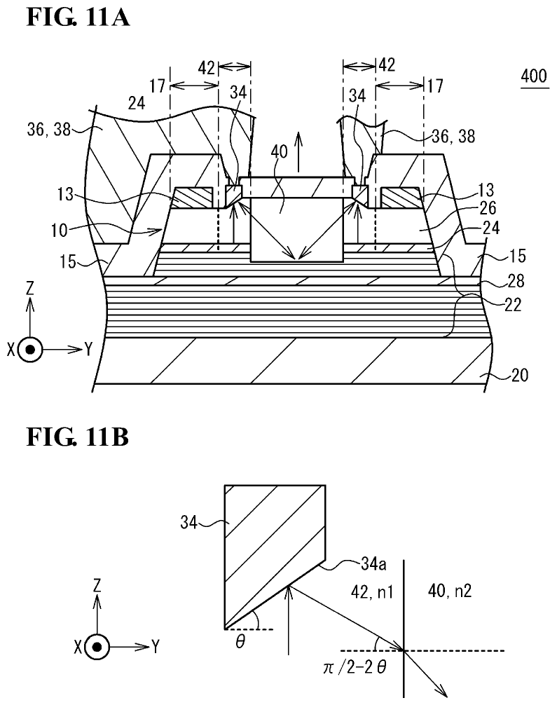

FIG. 11A is a sectional view illustrating, as an example, a surface emitting laser 400 according to a fourth embodiment. FIG. 11B is an enlarged sectional view of the electrode 34. The description of a configuration that is the same as that of any one of the first embodiment to the third embodiment will be omitted. As illustrated in FIG. 11A and FIG. 11B, the surface 34a of the electrode 34 is inclined with respect to the XY plane. The inclination angle θ is, for example, smaller than 45 degrees. The mesa 10 is not provided with the diffraction grating 48.

As indicated by arrows in FIG. 11A and FIG. 11B, light propagates through the electrically conductive region 42 and is reflected by the surface 34a of the electrode 34 so as to be incident on the electrically insulating region 40. As illustrated in FIG. 11B, the angle at which the light is incident on the electrically insulating region 40 from the electrically conductive region 42 is π/2-2θ. In FIG. 11B, the refractive index of the electrically conductive region 42 is denoted by n1. The refractive index of the electrically insulating region 40 is denoted by n2 and is equal to or lower than the refractive index n1 of the electrically conductive region 42.

The DBR layer 22 is provided below the electrically insulating region 40 and the electrically conductive region 42. Light is reflected by the surface 34a of the electrode 34, is incident on the electrically insulating region 40, and is reflected by the DBR layer 22. Multiple reflections of the light are repeated by the surface 34a and the DBR layer 22, and the light is emitted to the outside of the surface emitting laser 400. In the case where the inner periphery and the outer periphery of the electrically conductive region 42 are concentric with each other, only rotationally symmetric transverse mode light oscillates due to the symmetry of the shape of the electrically conductive region 42, and the light is emitted to the outside of the surface emitting laser 400.

In the case where the electrically insulating region 40 is formed by implanting ions into the DBR layer 26 and the active layer 24, the refractive index n2 of the electrically insulating region 40 is equal to the refractive index n1 of the electrically conductive region 42 or is about 1% lower than the refractive index n1. The angle of incidence π/2-2θ is set to an angle smaller than an angle (critical angle) at which light is fully reflected. For example, the angle θ of the surface 34a may be set to 4 degrees or larger and smaller than 45 degrees. The light is reflected by the surface 34a, is incident on the electrically insulating region 40, and is reflected by the DBR layer 22, which is positioned below the electrically insulating region 40 and the electrically conductive region 42.

The ion-implanted portion of the DBR layer 26 has an insulating property. The ion-implanted portion of the active layer 24 loses its optical activity. In contrast, also in the electrically insulating region 40, the DBR layers 22 and 26 and the active layer 24 function as a laser resonator. The light incident on the electrically insulating region 40 resonates in a manner similar to the light that propagates through the electrically conductive region 42, and is emitted from the top surface of the mesa 10 to the outside of the surface emitting laser 100.

In the case where the electrically insulating region 40 is made of an optical material, the refractive index n2 of the electrically insulating region 40 is lower than the refractive index n1 of the electrically conductive region 42. The angle of incidence π/2-2θ is set to an angle smaller than the critical angle. For example, the angle θ of the surface 34a may be set to 4 degrees or larger and smaller than 45 degrees. The light is reflected by the surface 34a, is incident on the electrically insulating region 40, and is reflected by the DBR layer 22, which is positioned below the electrically insulating region 40 and the electrically conductive region 42, so as to be emitted to the outside of the surface emitting laser.

According to the fourth embodiment, the heat-dissipation performance is improved, so that a temperature rise is suppressed. The modulation band of the surface emitting laser 400 can be increased. As indicated by arrows in FIG. 11A, light propagates through the electrically conductive region 42 and is reflected by the surface 34a of the electrode 34 so as to be incident on the electrically insulating region 40. The light is reflected by the surface 34a and the DBR layer 22 and is emitted upward in the Z-axis direction. According to the fourth embodiment, light can be efficiently extracted to the outside.

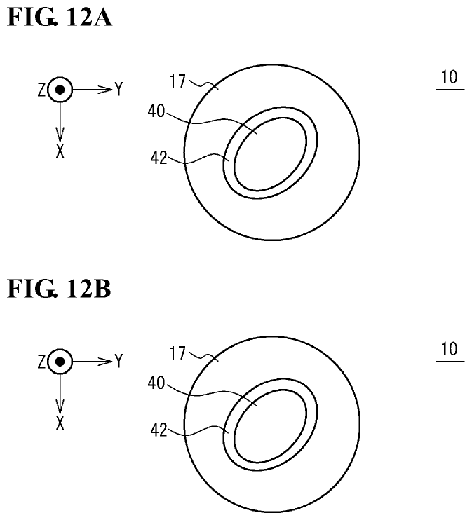

In the third embodiment and the fourth embodiment, as illustrated in FIG. 2, the electrically insulating region 40 and the electrically conductive region 42 are concentric with each other and rotationally symmetric to each other with respect to the optical axis (the Z axis). As a result of light being reflected as illustrated in FIG. 10A and FIG. 11A, a transverse mode that is rotationally symmetric with respect to the optical axis and that has an intensity distribution in the direction of the optical axis oscillates, and the light having a rotationally symmetric intensity distribution can be emitted in the Z-axis direction. As illustrated in FIG. 12A and FIG. 12B, the electrically insulating region 40 and the electrically conductive region 42 may each have a different shape.

FIG. 12A and FIG. 12B are each a plan view illustrating, as an example, a mesa 10 in a modification. In the case illustrated in FIG. 12A, the electrically insulating region 40 has an oval shape. The electrically conductive region 42 has an oval annular shape. In the case illustrated in FIG. 12B, the electrically insulating region 40 has a regular hexagonal shape. The electrically conductive region 42 has a hexagonal annular shape. The hexagonal annular shape is a ring-like shape having a regular hexagonal inner peripheral surface and a regular hexagonal outer peripheral surface. In FIG. 12B, each of the vertices of the electrically insulating region 40 faces one of the vertices of the electrically conductive region 42. In both the case illustrated in FIG. 12A and the case illustrated in FIG. 12B, the center of the electrically insulating region 40 and the center of the electrically conductive region 42 coincide with each other. As a result of light being repeatedly reflected, a transverse mode that is rotationally symmetric with respect to the optical axis and that has an intensity distribution in the direction of the optical axis oscillates. The shape of the electrically insulating region 40 in plan view and the shape of the electrically conductive region 42 in plan view may at least be similar to each other and rotationally symmetric with respect to the optical axis, and for example, it is preferable to have rotational symmetry of a six or more fold symmetry. A rotationally symmetric transverse mode oscillates and light can be extracted on the optical axis.

Although the embodiments of the present disclosure have been described in detail above, the present disclosure is not limited to the specific embodiments, and various modifications and changes can be made within the scope of the present disclosure as described in the claims.

What is claimed is:

1. A surface emitting laser comprising:
a first reflective layer;
an active layer provided on the first reflective layer; and
a second reflective layer provided on the active layer,
wherein the first reflective layer, the active layer, and the second reflective layer form a mesa,
wherein the mesa has an electrically insulating region and an electrically conductive region,
wherein the electrically insulating region is positioned at a center portion of the mesa in a surface direction, and
wherein the electrically conductive region includes the first reflective layer, the active layer, and the second reflective layer and is positioned outside the electrically insulating region in such a manner as to surround the electrically insulating region.

2. The surface emitting laser according to claim 1,
wherein the electrically insulating region is entirely surrounded by the electrically conductive region.

3. The surface emitting laser according to claim 1,
wherein the electrically insulating region is an ion-implanted region of the second reflective layer and an ion-implanted region of the active layer.

4. The surface emitting laser according to claim 1,
wherein the electrically insulating region is made of an optical material.

5. The surface emitting laser according to claim 1, further comprising:
an electrode disposed on a top surface of the electrically conductive region and electrically connected to the second reflective layer in the electrically conductive region,
wherein a surface of the electrode, the surface facing the second reflective layer, is inclined with respect to a top surface of the second reflective layer.

6. The surface emitting laser according to claim 5, further comprising:
a diffraction grating disposed on a top surface of the mesa in such a manner as to be positioned further toward an inner side than the electrode,
wherein an inclination angle of the surface of the electrode facing the second reflective layer is 45 degrees.

7. The surface emitting laser according to claim 5,
wherein an inclination angle of the surface of the electrode facing the second reflective layer is smaller than 45 degrees, and
wherein a refractive index of the electrically insulating region is equal to or lower than a refractive index of the electrically conductive region.

8. The surface emitting laser according to claim 1,
wherein a shape of the electrically insulating region in plan view and a shape of the electrically conductive region in plan view have rotational symmetry with respect to an optical axis.

9. A method for manufacturing a surface emitting laser comprising:
stacking a first reflective layer, an active layer, and a second reflective layer on top of one another in this order;
forming a mesa out of the first reflective layer, the active layer, and the second reflective layer; and
forming an electrically insulating region and an electrically conductive region in the mesa,
wherein the electrically insulating region is positioned at a center portion of the mesa in a surface direction, and
wherein the electrically conductive region includes the first reflective layer, the active layer, and the second reflective layer and is positioned outside the electrically insulating region in such a manner as to surround the electrically insulating region.
